(19) United States
(12) Patent Application Publication
(10) Pub. No.: US 2026/0238161 A1
(43) Pub. Date: Aug. 13, 2026

(54) Reducing Phase Noise for Oscillator Circuitry

(71) Applicant: Apple Inc., Cupertino, CA (US)

(72) Inventors: Rong Jiang, San Diego, CA (US); Chen Zhai, San Diego, CA (US); Chunwei Chang, San Jose, CA (US); Alireza Karimi Bidhendi, San Diego, CA (US)

(21) Appl. No.: 19/051,460

(22) Filed: Feb. 12, 2025

(51) Int. Cl. H03B 5/12

(52) U.S. Cl. CPC H03B 5/1212

(57) ABSTRACT

An oscillator is provided that include a first transistor having a source-drain terminal coupled to a first tail node, a second transistor cross-coupled with the first transistor and having a source-drain terminal coupled to the first tail node, a first coil coupled to the first tail node, and a first electrically floating tank magnetically coupled to the first coil. The first electrically floating tank may include a second coil and a first capacitor coupled across the second coil. The first coil and a second coil in the first electrically floating tank may form a transformer. The oscillator may further include third and fourth cross-coupled transistors coupled to a second tail node, a third coil coupled to the second tail node, and a second electrically floating tank magnetically coupled to the third coil. An oscillator configured in this way can provide improved phase noise performance.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless communications circuitry in the wireless communications circuitry uses the antennas to receive and transmit radio-frequency signals.

The wireless communications circuitry can include a transceiver having one or more mixers. A mixer in the transmit path can be used to modulate signals from a baseband frequency to a radio frequency, whereas a mixer in the receive path can be used to demodulate signals from the radio-frequency to the baseband frequency. Mixers receive clock signals generated from local oscillator circuitry. It can be challenging to design satisfactory local oscillator circuitry for an electronic device.

### SUMMARY

An aspect of the disclosure provides an oscillator that includes a first transistor having a first source-drain terminal coupled to a first tail node, a second transistor cross-coupled with the first transistor and having a first source-drain terminal coupled to the first tail node, a first coil coupled to the first tail node, and a first electrically floating tank magnetically coupled to the first coil. The oscillator can further include a first capacitor having a first terminal coupled to the first tail node and having a second terminal coupled to a power supply line, a second coil magnetically coupled to the first coil, where the first and second coils form part of a transformer; and a second capacitor coupled across the second coil. At least some of the first coil, the first capacitor, the second coil, and the second capacitor are configured to reject signals at a second harmonic of the oscillation frequency. The first and second capacitors can be fixed capacitors configured to provide reduced phase noise for the oscillator. The first and second capacitors can each be an adjustable capacitor controlled by only one bit.

An aspect of the disclosure provides an oscillator that includes a first pair of cross-coupled transistors coupled to a first tail node, a load inductor coupled to the first pair of cross-coupled transistors, a load capacitor across the load inductor, a first transformer coupled to the first tail node, and a first adjustable capacitor coupled across a primary coil of the first transformer, where the first adjustable capacitor is controlled by less than three control bits. The oscillator can further include a second pair of cross-coupled transistors coupled to a second tail node, a second transformer coupled to the second tail node, a second adjustable capacitor coupled across a primary coil of the second transformer, a third adjustable capacitor coupled across a secondary coil of the first transformer, and a fourth adjustable capacitor coupled across a secondary coil of the second transformer.

An aspect of the disclosure provides oscillator circuitry that includes a first complementary oscillator having a first output, a second complementary oscillator having a second output coupled in parallel with the first output, a first coil coupled between a first tail node of the first complementary oscillator and a ground power supply line, and a second coil coupled between a first tail node of the second complementary oscillator and a positive power supply line, where the first and second coils form part of a first transformer. The oscillator circuitry can further include a first capacitor coupled across the first coil and a second capacitor coupled across the second coil. The first and second capacitors can each include fixed capacitors or capacitors controlled by a single bit.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having oscillator circuitry in accordance with some embodiments.

FIG. 3 is a diagram of an illustrative oscillator having transformer-based phase noise filters in accordance with some embodiments.

FIG. 4 is a plot of phase noise as a function of frequency for an oscillator of the type shown in FIG. 3 in accordance with some embodiments.

FIG. 5 is a diagram of an illustrative oscillator having phase noise filters with coarse adjustment capacitors in accordance with some embodiments.

FIG. 6 is a plot of phase noise as a function of frequency for an oscillator of the type shown in FIG. 5 in accordance with some embodiments.

FIG. 7 is a diagram of illustrative dual core oscillator circuitry having transformer-based phase noise filters in accordance with some embodiments.

FIG. 8 is a plot of phase noise as a function of frequency for dual core oscillator circuitry of the type shown in FIG. 7 in accordance with some embodiments.

### DETAILED DESCRIPTION

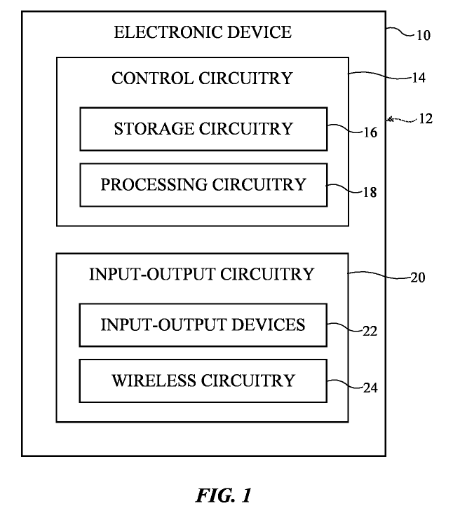

An electronic device such as electronic device 10 of FIG. 1 may be provided with wireless circuitry. The wireless circuitry can include one or more mixers and oscillator circuitry configured to generate oscillating signals or clock signals that are supplied to the one or more mixers. The oscillator circuitry can be a voltage controlled oscillator (VCO) having one or more inductors and a tunable capacitor. Such type of voltage controlled oscillator is sometimes referred to as an “LC” (inductor-capacitor) VCO. An LC VCO can include cross-coupled n-type transistors and cross-coupled p-type transistors. Such type of LC VCO is sometimes referred to as a “complementary” LC VCO.

In accordance with an embodiment, a complementary LC VCO can be provided with one or more phase noise filters or resonators coupled to the n-type and/or p-type transistors of the complementary LC VCO. The n-type transistors can be coupled to a first (n-side) phase noise filter, whereas the p-type transistors can be coupled to a second (p-side) phase noise filter. The first phase noise filter can include a first LC (inductor and capacitor based) tank magnetically coupled to a second LC tank via a first transformer. The second phase noise filter can include third LC tank magnetically coupled to a fourth LC tank via a second transformer. The first and second phase noise filters can have fixed capacitors or adjustable capacitors with coarse (e.g., single bit) tuning. The VCO can be configured to operate at an oscillation frequency, and the first and second phase noise filters can each be configured to selectively reject signals at a harmonic frequency such as a second harmonic of the oscillation frequency. Oscillator circuitry configured in this way can be technically advantageous and beneficial to provide improved phase noise performance over a wider frequency range while eliminating the calibration time that would otherwise be needed for fine tuning the capacitors of the phase noise filters.

In some embodiments, the oscillator circuitry can include first and second VCO circuits coupled together in parallel. Coupling two VCO circuits in parallel approximately reduces the effective inductance of the combined VCO by half and approximately doubles the total current injected into the load inductor, which can help further minimize phase noise. The first VCO can include a first (n-side) LC tank connected to its cross-coupled n-type transistors and a second (p-side) LC tank connected to its cross-coupled p-type transistors. The second VCO can include a third (n-side) LC tank connected to its cross-coupled n-type transistors and a fourth (p-side) LC tank connected to its cross-coupled p-type transistors. The first (n-side) LC tank of the first VCO can be magnetically coupled to the fourth (p-type) LC tank of the second VCO via a first transformer, whereas the second (p-side) LC tank of the first VCO can be magnetically coupled to the third (n-side) LC tank of the second VCO via a second transformer. Arranged in this way, the first and second transformers can be created by leveraging existing coils in the LC tanks of the two VCOs, thus providing a compact footprint.

The four LC tanks magnetically coupled together in this way via two transformers can form phase noise filter circuitry for the two VCOs. The phase noise filter circuitry can have coils and fixed capacitors. The VCOs can be configured to operate at an oscillation frequency, and the phase noise filter circuitry can be configured to selectively reject signals at a harmonic frequency such as a second harmonic of the oscillation frequency. Oscillator circuitry configured in this way can be technically advantageous and beneficial to provide improved phase noise performance over a wider frequency range while potentially eliminating the calibration time that would otherwise be needed for fine tuning the capacitors of the phase noise filter circuitry.

Electronic device 10 of FIG. 1 can include such types of oscillator with improved phase noise filter circuitry and may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user’s head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols – sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support or perform radio-frequency signal transmission and/or reception for device 10. Wireless circuitry 24 may be used for wireless communications. Wireless communications performed by wireless circuitry 24 may include or involve wireless data communications (e.g., where wireless data is carried by radio-frequency signals conveyed between wireless circuitry 24 and other communications equipment bidirectionally or unidirectionally), radio-frequency signal transmission, radio-frequency signal reception, and/or radio-based spatial ranging/sensing (e.g., radio detection and ranging (radar) operations, shorter range object detection such as near-field radio-frequency signal-based object detection, etc.). Radio-frequency signals conveyed by wireless circuitry 24 may include or carry wireless data (e.g., organized into frames, packets, symbols, datagrams, etc.), radar or other spatial ranging waveforms, continuous wave signals, chirp signals, control signals, management signals, reference signals, beacon signals, tones, pulses/impulses, waveforms associated with one or more communications protocols, and/or any other radio-frequency waveforms or signals. Wireless circuitry 24 is sometimes also referred to herein as wireless communications circuitry 24, wireless communication circuitry 24, communications circuitry 24, or simply as circuitry 24. Wireless circuitry 24 may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s). Some or all of the components of wireless circuitry 24 may be disposed on, mounted to, communicatively coupled to, and/or integrated within the same substrate (e.g., a printed circuit board, semiconductor substrate, chip, integrated circuit (IC), IC packages, etc.) or may be distributed between two or more substrates (e.g., printed circuit boards, semiconductor substrates, chips, ICs, IC packages, etc.).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or THF bands), etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

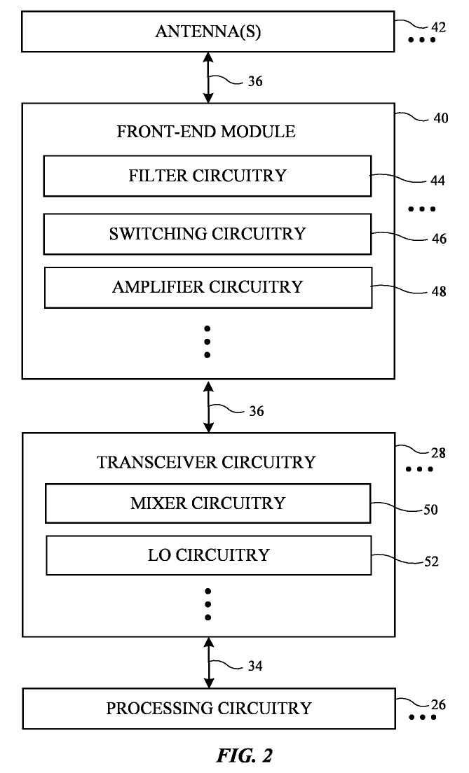

FIG. 2 is a diagram showing illustrative components within wireless circuitry 24. Wireless circuitry 24 can include, as part of oscillator circuitry 52, one or more phase noise filters with improved phase noise suppression capabilities. As shown in FIG. 2, wireless circuitry 24 may include one or more processors such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may be baseband processing circuitry, one or more application processor, one or more digital signal processor, one or more microcontroller, one or more microprocessor, one or more central processing unit (CPU), one or more programmable device, a combination of these circuits, and/or other types of processors within circuitry 18. Processing circuitry 26 may be configured to generate digital (transmit or baseband) signals. Processing circuitry 26 may be coupled to transceiver 28 over path 34 (sometimes referred to as a baseband path). Transceiver 28 may be coupled to antenna 42 via radio-frequency transmission line path 36. Radio-frequency front-end module 40 may be interposed on radio-frequency transmission line path 36 between transceiver 28 and antenna 42.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

In the example of FIG. 2, wireless circuitry 24 is illustrated as including a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective paths 34. Each transceiver 28 may include a transmitter circuit configured to output uplink signals to antenna 42, may include a receiver circuit configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module interposed thereon.

Front-end module (FEM) 40 may include radio-frequency front-end circuitry that operates on the radio-frequency signals conveyed (transmitted and/or received) over radio-frequency transmission line path 36. Front-end module 40 may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers and one or more low-noise amplifiers), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. The various front-end module components may be integrated into a single integrated circuit chip or may be formed as part of multiple integrated circuit chips.

Filter circuitry 44, switching circuitry 46, amplifier circuitry 48, and other circuitry may be interposed within radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards. In one suitable arrangement, radio-frequency transmission line paths such as radio-frequency transmission line path 36 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

In performing wireless transmission, processing circuitry 26 may provide digital signals to transceiver 28 over path 34. Transceiver 28 may further include circuitry for converting the baseband signals received from processing circuitry 26 into corresponding intermediate frequency or radio-frequency signals. For example, transceiver circuitry 28 may include mixer circuitry 50 for up-converting (or modulating) the baseband signals to intermediate frequencies or radio frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may include a transmitter component to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from external wireless equipment. The received radio-frequency signals may be conveyed to transceiver 28 via radio-frequency transmission line path 36 and front-end module 40. Transceiver 28 may include circuitry for converting the received radio-frequency signals into corresponding intermediate frequency or baseband signals. For example, transceiver 28 may use mixer circuitry 50 for downconverting (or demodulating) the received radio-frequency signals to baseband frequencies prior to conveying the received signals to processing circuitry 26 over path 34.

Transceiver 28 can include local oscillator circuitry such as local oscillator (LO) circuitry 52. Local oscillator circuitry 52 can generate oscillator or oscillating signals that mixer circuitry 50 uses to modulate transmitting signals from baseband frequencies to radio frequencies and/or to demodulate the received signals from radio frequencies to baseband or intermediate frequencies. Local oscillator circuitry 52 can generally include phase-locked loop (PLL) or delay-locked loop (DLL) circuitry configured to generate the oscillating signals being fed to inputs of mixer circuitry 50.

Conventional local oscillator circuitry can be implemented as a voltage controlled oscillator (VCO). The VCO can include a main tank and a secondary tank. The main tank includes a first inductor and a first capacitor array that is adjusted to control the oscillation frequency of the VCO. The secondary tank includes a second inductor and a second capacitor array. The second capacitor array needs to be calibrated to provide the desired phase noise rejection over different operating frequencies. Performing calibration of the secondary tank over a wide range of frequencies can be time consuming. The size of the second capacitor array is often large, which directly reduces the impedance of the secondary tank and thus degrades the amount of phase noise rejection.

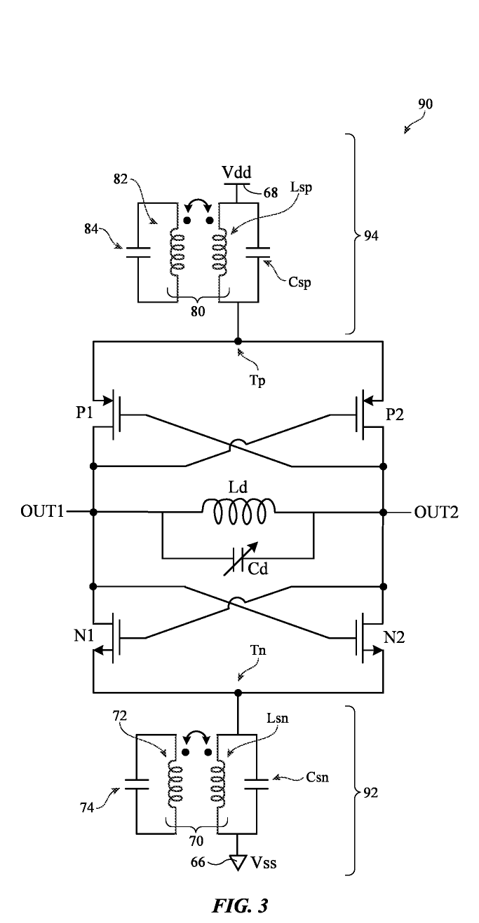

In accordance with an embodiment, an oscillator such as oscillator 90 of FIG. 3 provides improved phase noise rejection over a wide range of frequencies while reducing calibration time. Oscillator 90, sometimes referred to as an oscillator circuit, can represent an oscillator such as a voltage controlled oscillator (VCO) that may be part of a phase-locked loop (PLL) for generating oscillating signals in LO circuitry 52. As shown in FIG. 3, oscillator 90 can include n-type transistors N1 and N2, p-type transistors P1 and P2, an output capacitor such as tunable (adjustable) load capacitor Cd, and an output inductor such as load inductor Ld. Oscillator 90 that includes both n-type transistors and p-type transistors is sometimes referred to and defined herein as a “complementary” oscillator circuit.

Transistors N1 and N2 may be n-type (n-channel) transistors such as n-type metal-oxide-semiconductor (NMOS) devices. Transistor N1 may have a source terminal coupled to a first tail node such as tail node Tn, a drain terminal coupled to a first output terminal OUT1 of oscillator 90, and a gate terminal that is cross-coupled to a second output terminal OUT2 of oscillator 90. Transistor N2 may have a source terminal coupled to the first tail node Tn, a drain terminal coupled to the second output terminal OUT2, and a gate terminal that is cross-coupled to the first output terminal OUT1. Output terminals OUT1 and OUT2 may serve collectively as a differential output port of oscillator 90. Oscillating (local oscillator or “LO”) signals can be generated on the differential output port. Transistors N1 and N2 arranged in this way are sometimes referred to as “cross-coupled” differential n-type transistors.

The terms “source” and “drain” terminals used to refer to current-conveying terminals of a transistor may be used interchangeably and are sometimes referred to as “source-drain” terminals. Thus, the source terminal of transistor N1 can sometimes be referred to as a first source-drain terminal, and the drain terminal of transistor N1 can be referred to as a second source-drain terminal (or vice versa). The term “activate” with respect to a switch (or transistor) may refer to or be defined herein as an action that places the switch in an “on”or low-impedance state such that the two terminals of the switch are electrically connected to conduct current. The term “deactivate” with respect to a switch (or transistor) may refer to or be defined herein as an action that places the switch in an “off” or high-impedance state such that the two terminals of the switch/transistor are electrically disconnected with minimal leakage current.

At the other end, transistors P1 and P2 may be p-type (p-channel) transistors such as p-type metal-oxide-semiconductor (PMOS) devices. Transistor P1 may have a source terminal coupled to a second tail node such as tail node Tp, a drain terminal coupled to the first output terminal OUT1 of oscillator 90, and a gate terminal that is cross-coupled to the second output terminal OUT2 of oscillator 90. Transistor P2 may have a source terminal coupled to the second tail node Tp, a drain terminal coupled to the second output terminal OUT2, and a gate terminal that is cross-coupled to the first output terminal OUT1. Transistors P1 and P2 arranged in this way are sometimes referred to as “cross-coupled” differential p-type transistors.

Load (output) inductor Ld may have a first terminal coupled to output terminal OUT1 and a second terminal coupled to output terminal OUT2 (e.g., load inductor Ld may be coupled across the differential output port of oscillator 90). Tunable load (output) capacitor Cd may have a first terminal coupled to output terminal OUT1 and a second terminal coupled to output terminal OUT2. Load inductor Ld may thus be coupled in parallel with load capacitor Cd. Capacitor Cd may be implemented as a programmable bank of capacitors or other types of adjustable capacitive structure. Capacitor Cd can be adjusted to control an oscillation frequency of oscillator 90 and is sometimes referred to as an adjustable capacitor. The oscillation frequency of oscillator 90 is sometimes referred to as its “fundamental” frequency.

Oscillator 90 further includes one or more additional tank or resonator circuits. The term “tank” can be used herein to refer to a resonator that includes inductive and capacitive components, sometimes referred to herein as an LC based resonator. Oscillator 90 can further include a first tank circuit such as first tank circuit 92. First tank circuit 92 is coupled to tail node Tn is thus sometimes referred to as the first (n-side) “tail” tank circuit. First tail tank circuit 92 can include a coil Lsn, capacitor Csn, coil 72, and capacitor 74. Coil Lsn can have a first terminal coupled to tail node Tn and a second terminal coupled to a ground power supply line 66 (e.g., a ground line on which ground power supply voltage Vss is provided). Coil Lsn having one end shorted to a power supply terminal can be referred to as a “single-ended” or “shunt” inductor. Capacitor Csn can have a first terminal coupled to tail node Tn and a second terminal coupled to ground line 66. Capacitor Csn having one end shorted to a power supply terminal can be referred to as a “single-ended” or “shunt” capacitor.

Coil 72 may be magnetically (inductively) coupled to coil Lsn. Coils Lsn and 72 may form part of a first transformer 70. Coil Lsn may represent a primary coil (winding) of transformer 70, whereas coil 72 may represent a secondary coil (winding) of transformer 70. Coil 72 has a first terminal and a second terminal. Capacitor 74 has a first terminal coupled to the first terminal of coil 72 and has a second terminal coupled to the second terminal of coil 72. Connected in this way, coil 72 and capacitor 74 are considered to be coupled together “in parallel” (e.g., capacitor 74 is coupled across the terminals of coil 72). Coil 72 and capacitor 74 are not actively shorted to a power supply line and can thus collectively be considered part of an electrically “floating” tank or LC resonator.

First tank circuit 92 arranged in this way can be configured to provide rejection of signals at harmonic frequencies (e.g., at integer multiples of the fundamental oscillation frequency of circuit 90). For example, first tank circuit 92 can be configured to reject signals at the second harmonic frequency (e.g., at two times the fundamental frequency) and can thus sometimes be referred to as a second harmonic (H2) tank or resonator circuit. The use of transformer 70 within tank circuit 92 can be technically advantageous and beneficial to provide a wideband high impedance, thus achieving the desired phase noise over a wider range of frequencies without trimming. This allows capacitors Csn and 74 to be fixed (non-adjustable) capacitors. The use of fixed capacitors Csn and 74 instead of programmable capacitor arrays that are used in conventional VCOs increases the quality (Q) factor of tank circuit 92 while reducing the parasitic capacitance at tail node Tn, which enables the use of higher inductance for coil Lsn, all producing the maximal impedance at the H2 frequency to further minimize the phase noise of oscillator 90. Tank circuit 92 operated in this way is thus sometimes referred to herein as a tail phase noise filter.

The example above in which first tank circuit 92 is configured to resonate or reject signals at the H2 frequency is illustrative. In other embodiments, first tank circuit 92 can alternatively be configured to reject signals at a third harmonic (H3) frequency, at a fourth harmonic (H4) frequency, at a fifth harmonic (H5) frequency, at other harmonic frequencies, and/or at other suitable frequencies.

Oscillator 90 can further include a second tank circuit such as second tank circuit 94. Second tank circuit 94 is coupled to tail node Tp is thus sometimes referred to as the second (p-side) “tail” tank circuit. Second tail tank circuit 94 can include a coil Lsp, capacitor Csp, coil 82, and capacitor 84. Coil Lsp can have a first terminal coupled to tail node Tp and a second terminal coupled to a positive power supply line 68 (e.g., a positive power supply terminal on which positive power supply voltage Vdd is provided). Coil Lsp having one end shorted to a power supply terminal can be referred to as a “single-ended” or “shunt” inductor. Capacitor Csp can have a first terminal coupled to tail node Tp and a second terminal coupled to the Vdd power supply line 68. Capacitor Csp having one end shorted to a power supply terminal can be referred to as a “single-ended” or “shunt” capacitor.

Coil 82 may be magnetically (inductively) coupled to coil Lsp. Coils Lsp and 82 may form part of a second transformer 80. Coil Lsp may represent a primary coil (winding) of transformer 80, whereas coil 82 may represent a secondary coil (winding) of transformer 80. Coil 82 has a first terminal and a second terminal. Capacitor 84 has a first terminal coupled to the first terminal of coil 82 and has a second terminal coupled to the second terminal of coil 82. Connected in this way, coil 82 and capacitor 84 are considered to be coupled together “in parallel” (e.g., capacitor 84 is coupled across the terminals of coil 82). Coil 82 and capacitor 84 are not actively shorted to a power supply line and can thus collectively be considered part of an electrically “floating” tank or LC resonator. The n-side LC resonator that includes components 72 and 74 may be configured to resonate at a first frequency, whereas the p-side LC resonator that includes components 82 and 84 may optionally be configured to resonate at a second frequency different than the first frequency (e.g., the n-side and p-side tanks can be configured to resonate at different frequencies to further improve phase noise). In other embodiments, the n-side and p-side tanks can be configured to resonate at the same frequency.

Second tank circuit 94 arranged in this way can be configured to provide rejection of signals at harmonic frequencies (e.g., at integer multiples of the fundamental oscillation frequency of circuit 90). For example, second tank circuit 94 can be configured to reject signals at the second harmonic frequency (e.g., at two times the fundamental frequency) and can thus sometimes be referred to as a second harmonic (H2) tank or resonator circuit. This is illustrative. If desired, first tank circuit 92 and second tank circuit 94 can be configured to resonate at different resonant frequencies to provide wideband phase noise rejection. The use of transformer 80 within tank circuit 94 can be technically advantageous and beneficial to provide a wideband high impedance, thus achieving the desired phase noise over a wider range of frequencies without trimming. This allows capacitors Csp and 84 to be fixed (non-adjustable) capacitors. The use of fixed capacitors Csp and 84 instead of programmable capacitor arrays that are used in conventional VCOs increases the quality (Q) factor of tank circuit 94 while reducing the parasitic capacitance at tail node Tp, which enables the use of higher inductance for coil Lsp, all producing the maximal impedance at the H2 frequency to further minimize the phase noise of oscillator 90. Tank circuit 94 operated in this way is thus sometimes referred to herein as a tail phase noise filter.

The example above in which second tank circuit 94 is configured to resonate or reject signals at the H2 frequency is illustrative. In other embodiments, second tank circuit 94 can be configured to reject signals at the same frequency as first tank circuit 92, at different frequencies than first tank circuit 92, at a third harmonic (H3) frequency, at a fourth harmonic (H4) frequency, at a fifth harmonic (H5) frequency, at other harmonic frequencies, and/or at other suitable frequencies.

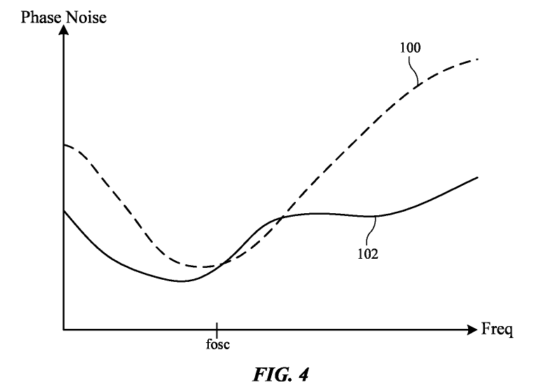

FIG. 4 is a plot of phase noise as a function of frequency for oscillator circuit 90 of the type described in connection with FIG. 3 in accordance with some embodiments. Curve 100 represents the phase noise profile for a conventional LC VCO. Curve 100 may exhibit low phase noise at oscillation frequency f_{OSC}. Frequency f_{OSC} may represent the fundamental frequency of the LC VCO. On the other hand, curve 102 represents the phase noise profile of oscillator 90 of FIG. 3. In contrast to curve 100, curve 102 exhibits reduced phase noise over a wider range of frequencies around frequency f_{OSC}. FIG. 4 thus illustrates how oscillator 90 provides a more wideband phase noise reduction. Such frequency response provides enhanced immunity to frequency variations and thus lowers the trimming requirements that would otherwise be needed for the tail capacitors (see, e.g., capacitors Csn, 74, Csp, and 84 in FIG. 3).

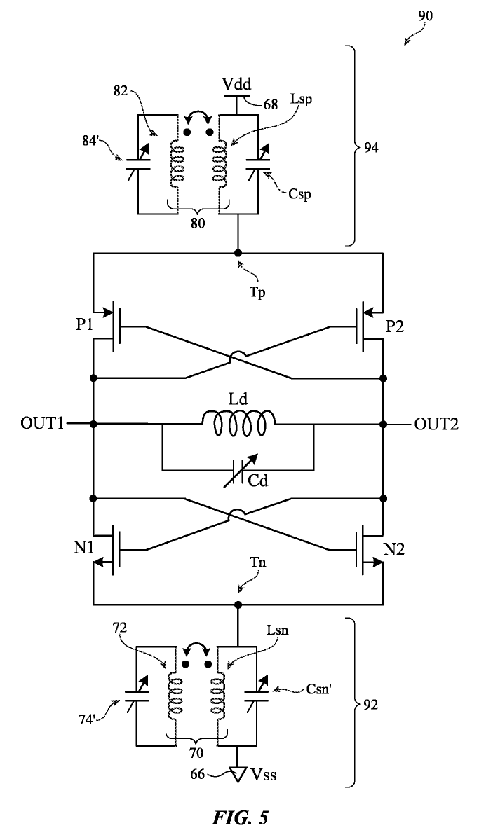

The embodiment of FIG. 3 in which capacitors Csn, 74, Csp, and 84 within the phase noise filters are fixed capacitors is exemplary. FIG. 5 shows another embodiment of oscillator 90 in which the capacitors in the phase noise filters are coarse adjustable. As shown in FIG. 5, capacitors Csn’ and 74’ of the n-side tank circuit 92 can be adjustable capacitors. As an example, capacitors Csn’ and 74’ can each be a one-bit adjustable capacitor (e.g., a coarse adjustable capacitor having a variable capacitance tunable using a single control bit). In other words, capacitors Csn’ and 74’ are configured to be controlled by a respective single control bit (e.g., capacitor Csn’ is controlled by a first control bit, whereas capacitor 74’ can be controlled by a second control bit or optionally by the first control bit). When the control bit is high, capacitors Csn’ and 74’ can exhibit a higher (elevated) capacitance. When the control bit is low, capacitors Csn’ and 74’ can exhibit a lower (reduced) capacitance. Capacitors Csn’ and 74’ should be adjusted in same direction (e.g., the capacitance of capacitors Csn’ and 74’ should both be increased or both be decreased). Increasing the capacitance of capacitors Csn’ and 74’ can lower the frequency of the phase noise rejection, whereas decreasing the capacitance of capacitors Csn’ and 74’ can increase the frequency of the phase noise rejection. This example in which capacitors Csn’ and 74’ are coarsely adjustable using only one control bit is illustrative. If desired, capacitors Csn’ and 74’ can each be controlled using less than two control bits, less than three control bits, less than four control bits, or less than five control bits. Limiting the number of control bits for adjusting capacitors Csn’ and 74’ can help keep the Q factor of tank circuit 92 at a relatively high level to optimize for phase noise rejection.

At the other end, capacitors Csp’ and 84’ of the p-side tank circuit 94 can also be adjustable capacitors. As an example, capacitors Csp’ and 84’ can each be a one-bit adjustable capacitor (e.g., a coarse adjustable capacitor having a variable capacitance tunable using a single control bit). In other words, capacitors Csp’ and 84’ are configured to be controlled by a respective single control bit (e.g., capacitor Csp’ is controlled by a third control bit, whereas capacitor 84’ can be controlled by a fourth control bit or optionally by the third control bit). When the control bit is high, capacitors Csp’ and 84’ can exhibit a higher (elevated) capacitance. When the control bit is low, capacitors Csp’ and 84’ can exhibit a lower (reduced) capacitance. The control bit for tuning capacitors Csn’ and 74’ can be the same or different than the control bit for tuning capacitors Csp’ and 84’. The remaining structure of oscillator 90 is similar to that which is already described in connection with FIG. 3 and need not be reiterated in detail to avoid obscuring the present embodiment.

Capacitors Csp’ and 84’ should be adjusted in same direction (e.g., the capacitance of capacitors Csp’ and 84’ should both be increased or both be decreased). Increasing the capacitance of capacitors Csp’ and 84’ can lower the frequency of the phase noise rejection, whereas decreasing the capacitance of capacitors Csp’ and 84’ can increase the frequency of the phase noise rejection. The capacitance of capacitors Csp’ and 84’ should also be adjusted in the same direction as the capacitance of capacitors Csn’ and 74’ (e.g., the capacitance of all tunable capacitors within circuits 92 and 94 should either all be increased or all be decreased in tandem). This example in which capacitors Csp’ and 84’ are coarsely adjustable using only one control bit is illustrative. If desired, capacitors Csp’ and 84’ can each be controlled using less than two control bits, less than three control bits, less than four control bits, or less than five control bits. Limiting the number of control bits for adjusting capacitors Csp’ and 84’ can help keep the Q factor of tank circuit 94 at a relatively high level to optimize for phase noise rejection.

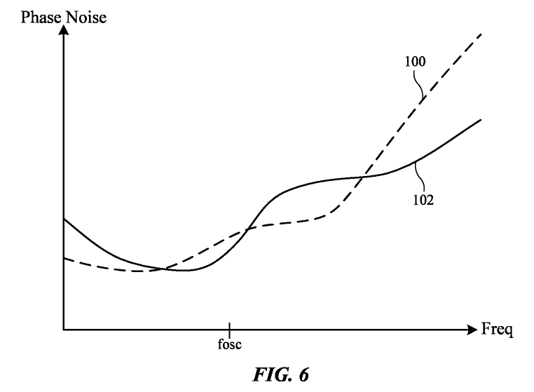

FIG. 6 is a plot of phase noise as a function of frequency for oscillator 90 of the type described in connection with FIG. 5. Curve 102 represents the phase noise profile of oscillator 90 with a coarse bit set to a value of zero. Curve 102 may exhibit low phase noise at oscillation frequency f_{OSC}. Frequency f_{OSC} may represent the fundamental frequency of oscillator 90. On the other hand, curve 104 represents the phase noise profile of oscillator 90 with a coarse bit set to a value of one. Curve 104 exhibits an even lower phase noise at a frequency less than f_{OSC}. In other words, FIG. 6 shows how curve 102 favors a higher oscillation frequency, whereas curve 104 favors a relatively lower oscillation frequency. Such adjustable frequency response provides enhanced immunity to frequency variations and thus lowers the trimming requirements that would otherwise be needed for the tail capacitors (see, e.g., capacitors Csn’, 74’, Csp’, and 84’ in FIG. 5).

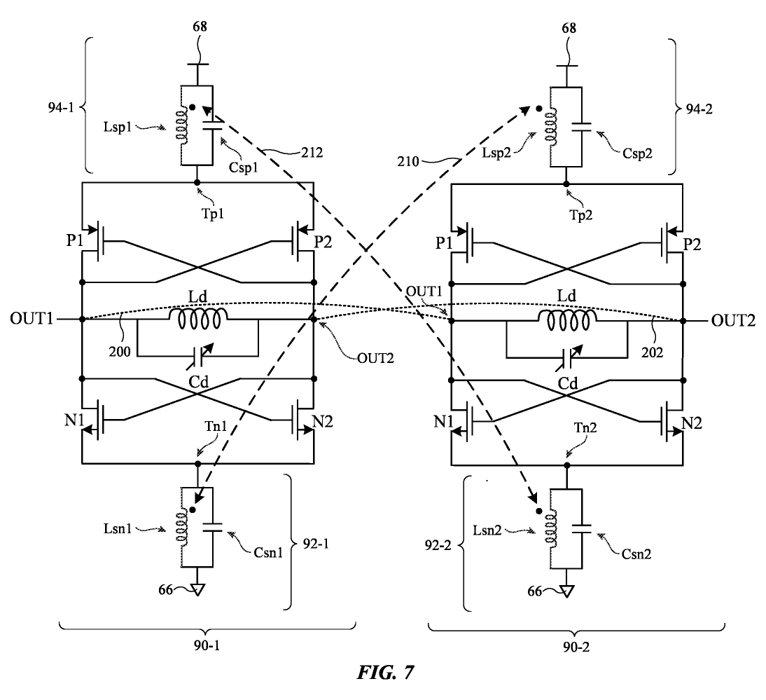

The embodiments of FIGS. 3 and 5 in which the oscillator circuitry includes one complementary VCO are illustrative. FIG. 7 illustrates another embodiment of oscillator circuitry that includes multiple LC-based VCOs. As shown in FIG. 7, the oscillator circuitry can include a first oscillator circuit 90-1 coupled in parallel with a second oscillator circuit 90-2. First oscillator circuit 90-1 can include a first pair of cross-coupled n-type transistors N1 and N2 coupled to tail node Tn1, a first pair of cross-coupled p-type transistors P1 and P2 coupled to tail node Tp1, and first load inductor Ld and first load (adjustable) capacitor Cd coupled between output terminals OUT1 and OUT2.

An LC tank 92-1 may be coupled to tail node Tn1. Tank 92-1 may include coil Lsn1 and capacitor Csn1 coupled together in parallel. In particular, coil Lsn1 may have a first terminal coupled to tail node Tn1 and a second terminal coupled to ground line 66. Capacitor Csn1 may have a first terminal coupled to tail node Tn1 and a second terminal coupled to ground line 66. At the other end, an LC tank 94-1 may be coupled to tail node Tp1. Tank 94-1 may include coil Lsp1 and capacitor Csp1 coupled together in parallel. In particular, coil Lsp1 may have a first terminal coupled to tail node Tp1 and a second terminal coupled to positive power supply line 68. Capacitor Csp1 may have a first terminal coupled to tail node Tp1 and a second terminal coupled to positive power supply line 68. LC tanks 92-1 and 94-1 may be considered part of the first oscillator 90-1.

The second oscillator circuit 90-2 can include a second pair of cross-coupled n-type transistors N1 and N2 coupled to tail node Tn2, a second pair of cross-coupled p-type transistors P1 and P2 coupled to tail node Tp2, and second load inductor Ld and second load (adjustable) capacitor Cd coupled between output terminals OUT1 and OUT2. In particular, terminal OUT1 of oscillator circuit 90-2 may be shorted to terminal OUT1 of oscillator circuit 90-1 via the connection shown by dotted line 200, whereas terminal OUT2 of oscillator circuit 90-2 may be shorted to terminal OUT2 of oscillator circuit 90-1 via the connection shown by dotted line 202. In other words, first complementary oscillator circuit 90-1 and second complementary oscillator circuit 90-2 can be considered to be coupled together “in parallel,” sharing a common differential output port. Connecting two or more VCOs in parallel can be beneficial to reduce the effective inductance at the output port, which can double the current injected into the load inductors.

Second oscillator circuit 90-2 can further include LC tanks 92-2 and 94-2. Tank 92-2 may be coupled to tail node Tn2. Tank 92-2 may include coil Lsn2 and capacitor Csn2 coupled together in parallel. In particular, coil Lsn2 may have a first terminal coupled to tail node Tn2 and a second terminal coupled to ground line 66. Capacitor Csn2 may have a first terminal coupled to tail node Tn2 and a second terminal coupled to ground line 66. At the other end, tank 94-2 may be coupled to tail node Tp2. Tank 94-2 may include coil Lsp2 and capacitor Csp2 coupled together in parallel. In particular, coil Lsp2 may have a first terminal coupled to tail node Tp2 and a second terminal coupled to positive power supply line 68. Capacitor Csp2 may have a first terminal coupled to tail node Tp2 and a second terminal coupled to positive power supply line 68.

Moreover, coil Lsn1 may be magnetically coupled to coil Lsp2 (as shown by arrows 210) to form a first transformer. Coil Lsn1 may overlap with coil Lsp2 when viewed from a plan/layout perspective to provide a compact inductor footprint (e.g., coil Lsn1 may be disposed directly on top of or adjacent to coil Lsp2, or vice versa). At the other ends, coil Lsn2 may be magnetically coupled to coil Lsp1 (as shown by arrows 212) to form a second transformer. Coil Lsn2 may overlap with coil Lsp1 when viewed from a plan/layout perspective to provide a compact inductor footprint (e.g., coil Lsn1 may be disposed directly on top of or adjacent to coil Lsp2, or vice versa).

Coils Lsn1 and Lsn2 may have equal inductance. Capacitors Csn1 and Csn2 may have equal capacitance. Coils Lsp1 and Lsp2 may have equal inductance. However, the inductance of coils Lsp1 and Lsp2 need not be equal to the inductance of coils Lsn1 and Lsn2. Capacitors Csp1 and Csp2 may have equal capacitance. However, the capacitance of capacitors Csp1 and Csp2 need not be equal to the capacitance of capacitors Csn1 and Csn2. In accordance with some embodiments, coils Lsn1 and Lsp1 can have different inductance values, and capacitors Csn1 and Csp1 can have different capacitance values. Having different inductance and capacitance values at opposing n and p sides of the two VCOs 90-1 and 90-2 can be technically advantageous to provide a more wideband phase noise rejection.

The use of the two transformers cross-coupled between oscillator circuits 90-1 and 90-2 in this way can be technically advantageous and beneficial to provide a wideband high impedance, thus achieving the desired phase noise over a wider range of frequencies without trimming. This allows capacitors Csn1, Csn2, Csp1, and Csp2 to be fixed (non-adjustable) capacitors. The use of fixed capacitors instead of programmable capacitor arrays that are used in conventional VCOs increases the quality (Q) factor of tanks 92-1, 92-2, 94-1, and 94-2, which enables the use of higher inductance for coils Lsn1, Lsn2, Lsp1, and Lsp2, all producing the maximal impedance at some harmonic frequency (e.g., at the second harmonic or other harmonic frequency) to further minimize the phase noise of the overall oscillator circuitry. In other embodiments, capacitors Csn1, Csn2, Csp1, and Csp2 can be coarsely adjustable capacitors (e.g., capacitors tunable using no more than one, two, or three control bits). Tanks 92-1, 92-2, 94-1, and 94-2 operated in this way are thus sometimes referred to herein collectively as transformer based tail phase noise filter circuitry.

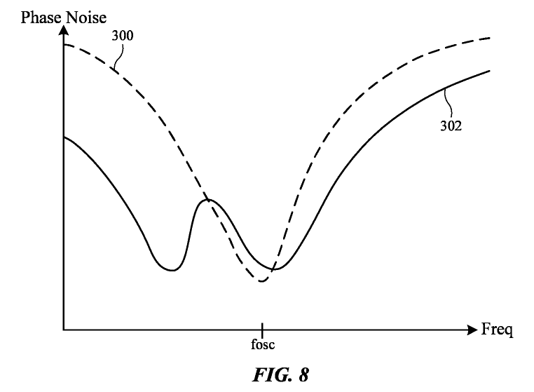

FIG. 8 is a plot of phase noise as a function of frequency for the oscillator circuitry of the type described in connection with FIG. 7. Curve 300 represents the phase noise profile of a conventional LC VCO. Curve 300 may exhibit a relatively narrowband phase noise rejection response near oscillation frequency f_{OSC}. On the other hand, curve 302 represents the phase noise profile of the dual VCO oscillator circuitry of FIG. 7. In contrast to curve 300, curve 302 exhibits a wider range of reduced phase noise around frequency f_{OSC}. In particular, curve 302 exhibits multiple valleys produce from the different resonant frequencies of tanks 92-1, 92-2, 94-1, and 94-2. Such frequency response provides enhanced immunity to frequency variations and thus lowers the trimming requirements that would otherwise be needed for the tail capacitors.

The methods and operations described above in connection with FIGS. 1-8 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. An oscillator configured to output an oscillating signal having an oscillation frequency, the oscillator comprising:
a first transistor having a first source-drain terminal coupled to a first tail node;
a second transistor cross-coupled with the first transistor and having a first source-drain terminal coupled to the first tail node;
a first coil coupled to the first tail node; and
a first electrically floating tank magnetically coupled to the first coil.

2. The oscillator of claim 1, further comprising:
a load inductor having a first terminal coupled to a second source-drain terminal of the first transistor and having a second terminal coupled to a second source-drain terminal of the second transistor; and
an adjustable load capacitor coupled across the first and second terminals of the load inductor.

3. The oscillator of claim 1, further comprising:
a first capacitor having a first terminal coupled to the first tail node and having a second terminal coupled to a power supply line, wherein the first coil is coupled in parallel with the first capacitor.

4. The oscillator of claim 3, wherein the first electrically floating tank comprises:
a second coil magnetically coupled to the first coil, wherein the first and second coils form part of a transformer; and
a second capacitor coupled across the second coil.

5. The oscillator of claim 4, wherein at least some of the first coil, the first capacitor, the second coil, and the second capacitor are configured to reject signals at a second harmonic of the oscillation frequency.

6. The oscillator of claim 4, wherein the first and second capacitors comprise fixed capacitors configured to provide reduced phase noise for the oscillator.

7. The oscillator of claim 4, wherein the first and second capacitors each comprise an adjustable capacitor controlled by only one bit.

8. The oscillator of claim 4, further comprising:
a third transistor having a first source-drain terminal coupled to a second tail node different than the first tail node;
a fourth transistor cross-coupled with the third transistor and having a first source-drain terminal coupled to the second tail node;
a second coil coupled to the second tail node; and
a second electrically floating tank magnetically coupled to the second coil.

9. The oscillator of claim 8, wherein the first electrically floating tank is configured to resonate at a first frequency, and wherein the second electrically floating tank is configured to resonate at a second frequency different than the first frequency.

10. An oscillator comprising:
a first pair of cross-coupled transistors coupled to a first tail node;
a load inductor coupled to the first pair of cross-coupled transistors;
a load capacitor across the load inductor;
a first transformer coupled to the first tail node; and
a first adjustable capacitor coupled across a primary coil of the first transformer, wherein the first adjustable capacitor is configured to be controlled by fewer than three control bits.

11. The oscillator of claim 10, further comprising:
a second pair of cross-coupled transistors coupled to a second tail node; and
a second transformer coupled to the second tail node.

12. The oscillator of claim 11, further comprising:
a second adjustable capacitor coupled across a primary coil of the second transformer, wherein the first and second adjustable capacitors are configured to be controlled by a respective single control bit.

13. The oscillator of claim 12, further comprising:
a third adjustable capacitor coupled across a secondary coil of the first transformer, wherein the third adjustable capacitor and the first adjustable capacitor are configured to be controlled by a same control bit.

14. The oscillator of claim 13, further comprising:
a fourth adjustable capacitor coupled across a secondary coil of the second transformer, wherein the fourth adjustable capacitor and the second adjustable capacitor are configured to be controlled by a same control bit.

15. The oscillator of claim 14, wherein the oscillator is configured to output an oscillating signal having an oscillation frequency, and wherein at least the first adjustable capacitor, the first transformer, and the third adjustable capacitor are configured to reject signals at a second harmonic of the oscillation frequency.

16. Oscillator circuitry comprising:
a first complementary oscillator having a first output;
a second complementary oscillator having a second output coupled in parallel with the first output;
a first coil coupled between a first tail node of the first complementary oscillator and a ground power supply line; and
a second coil coupled between a first tail node of the second complementary oscillator and a positive power supply line, wherein the first and second coils form part of a first transformer.

17. The oscillator circuitry of claim 16, further comprising:
a first capacitor coupled across the first coil; and
a second capacitor coupled across the second coil.

18. The oscillator circuitry of claim 17, wherein the first and second capacitors respectively comprise fixed capacitors or capacitors configured to be controlled by a single bit.

19. The oscillator circuitry of claim 17, further comprising:
a third coil coupled to a second tail node of the first complementary oscillator and the positive power supply line; and
a fourth coil coupled to a second tail node of the second complementary oscillator and the ground power supply line, wherein the third and fourth coils form part of a second transformer.

20. The oscillator circuitry of claim 19, further comprising:
a third fixed or adjustable capacitor coupled across the third coil; and
a fourth fixed or adjustable capacitor coupled across the fourth coil.
